(19) United States
(12) Patent Application Publication
(10) Pub. No.: US 2005/0112853 A1
(43) Pub. Date: May 26, 2005

(54) System and method for non-destructive implantation characterization of quiescent material

(76) Inventors: Raymond Kuzbyt, Boulder Creek, CA (US); Ronald J. Eddy, Wickenburg, AZ (US); Marylou M. Meloni, So. Hamilton, MA (US)

Correspondence Address: PATENT GROUP;CHOATE, HALL & STEWART, EXCHANGE PLACE, 53 STATE STREET, BOSTON, MA, 02109, US

(21) Appl. No.: 10/721,235

(22) Filed: Nov. 26, 2003

(51) Int. Cl. H01L 21/66

(52) U.S. Cl. 438/514

(57) ABSTRACT

Light from a light source is directed towards a plurality of measurement points on a substrate to characterize the substrate based on light reflectivity. In a differential approach, light is directed onto the substrate before and after dopant implantation. Reflected light is detected and analyzed for spectral distribution and intensity. A differential measurement is derived, from which implantation uniformity is determined.

### CROSS-REFERENCE TO RELATED APPLICATIONS

(Not applicable)

### BACKGROUND OF THE INVENTION

1. Field of the Invention

The present invention relates generally to optical methods and apparatus for use in ion implantation dosage, measurement of energy and depth.

2. Description of Related Art

Precise measurement of ion implantation characteristics is of profound importance in the art of integrated circuit (IC) fabrication. The requirements of high density, large scale integration have placed tremendous burdens on inspection and measurement techniques. For example, the ability to accurately measure dopant concentration for control of implantation parameters is paramount to efficient, cost-effective semiconductor device manufacture. Precisely controlled dopant concentrations are important for instance because smaller circuit features impose tighter dose distribution parameters with regard to energy and concentration. Accurate measurement of these parameters plays a critical role in the continuing trend towards further miniaturization and scalability, and towards accurate control of device characteristics as required for high yield and specific types of applications.

Various approaches have been taken for measuring implantation characteristics. One prior art optical approach to determining implantation conditions utilizes the effect known as modulated optical reflectivity (MOR), wherein two monochromatic light beams, from separate laser souces for instance, are directed confocally onto the substrate under test. The first light beam induces excitations in the material, which excitations are a function of a measured parameter, such as implantation density. The second light beam is a reading beam, whose reflection by the surface is measured to provide an indication of the measured parameter. Two prior art references, U.S. Pat. No. 5,034,611 (Alpern, et al.) and U.S. Pat. No. 5,769,540 (Schietinger, et al.) are directed to this MOR approach.

The MOR approach suffers from several disadvantages, including low sensitivity, inadequate spacial resolution, and limited repeatability. Specifically, while this approach is purportedly non-destructive, there is evidence that the excitation beam in the MOR technique in actuality alters the substrate material at the atomic level, and this alteration is cumulative in effect, such that repeated tests of a specific site result in changes to the material and yield inaccurate measurement results. It is believed that the alterations at least in part contribute to changes in the implantation measurement, wherein the implantation site is locally “damaged” by the high thermal state of the substrate caused by the excitation laser. The claims of non-destructiveness are further complicated by the fact that the MOR effect itself, and its underlying causes, are not entirely understood. Further, the MOR approach is high in cost because of its need for high energy, monochromatic coherent light from multiple light sources. In addition, the excitation and subsequent reading processes consume an unacceptable amount of time for each test incident, which, in the aggregate, severely limits the number of tests per wafer which can be performed in a production environment, especially for larger-sized substrates. In particular, it takes several milliseconds of exposure to the excitation laser light in order to reach the level of excitation required to derive a meaningful reading by the reading light. Over multiple readings, the measurement duration per wafer becomes impractical.

### BRIEF SUMMARY OF THE INVENTION

In accordance with the invention, there is provided a method for measuring one or more characteristics of implantation in a substrate. The method includes, before implantation, directing non-destructive light onto a quiescent substrate at a first set of one or more measurement points to thereby cause light reflection by the substrate, and detecting the light reflection. After implantation, non-destructive light is directed onto the substrate at the first set of one or more measurement points to thereby cause light reflection by the substrate, and light reflection is detected. The method further includes correlating the detected light reflection before implantation to the detected light reflection after implantation to obtain one or more differential measurement values each associated with a corresponding measurement point and indicative of an implantation characteristic of the substrate at the corresponding measurement point.

Further in accordance with the invention, there is provided a method for generating an implantation characteristic profile of a quiescent substrate, wherein the substrate is non-destructively illuminated at a plurality of measurement points prior to implantation. For each illuminated measurement point prior to implantation, a spectral distribution and intensity of reflected light is detected. The substrate is also non-destructively illuminated at a plurality of measurement points after implantation, and for each illuminated measurement point after implantation, a spectral distribution and intensity of reflected light is detected. A map is generated of differential measurement values each associated with a corresponding measurement point and indicative of an implantation characteristic of the substrate at the corresponding measurement point.

Further in accordance with the invention, there is provided a device for non-destructively measuring dopant concentration in a substrate, including a light source, a light detector generating a detection signal in response to light impinging on the light detector, an optical system directing light from the light source to an illumination area on the substrate and directing light reflected by the substrate from the illumination area onto the light detector, a stage for relatively moving the substrate in first and second scanning patterns, and a processor which, during the first scanning pattern, obtains from the light detector a first set of detection signals each corresponding to a measurement point on the substrate, and during the second scanning pattern, obtains from the light detector a second set of detection signals each corresponding to each of said measurement points, such that for each measurement point, a pair of detection signals are obtained. The processor further generates a set of differential measurement values each derived from one of the pair of detection signals, the set of differential measurement values being indicative of implantation characteristic levels in the substrate, including any of dopant concentration, dose, energy and depth.

Further in accordance with the invention, a method for characterizing a substrate is taught, the method including directing non-destructive light onto a surface of a substrate in a quiescent state at a plurality of measurement points on the substrate to thereby cause light reflection by the substrate, detecting light reflected from the substrate at the plurality of measurement points, and using the detected reflected light to generate a map indicative of relative reflectivity across the surface of the substrate.

### BRIEF DESCRIPTION OF THE SEVERAL VIEWS OF THE DRAWING(S)

Many advantages of the present invention will be apparent to those skilled in the art with a reading of this specification in conjunction with the attached drawings, wherein like reference numerals are applied to like elements.

FIG. 1 is a diagrammatical view of a system and method in accordance with the invention;

FIG. 1A is a diagrammatical view of further embodiment system and method in accordance with the invention;

FIG. 2 is a view of a scanning pattern in accordance with the invention;

FIGS. 3A and 3B are two dimensional and three dimensional views of displayed mappings of detected implantation characteristics pertaining to a defective implantation process;

FIGS. 4A and 4B are two dimensional and three dimensional views of displayed mappings of detected implantation characteristics pertaining to a non-defective implantation process;

FIG. 5 is a diagrammatical view illustrating a scanning process for scanning a portion of a substrate in accordance with the invention; and

FIG. 6 is a diagrammatical view of a further system and method illustrating the scanning of a substrate in an ion implanter for real-time dose monitoring and control in accordance with the invention.

### DETAILED DESCRIPTION OF THE INVENTION

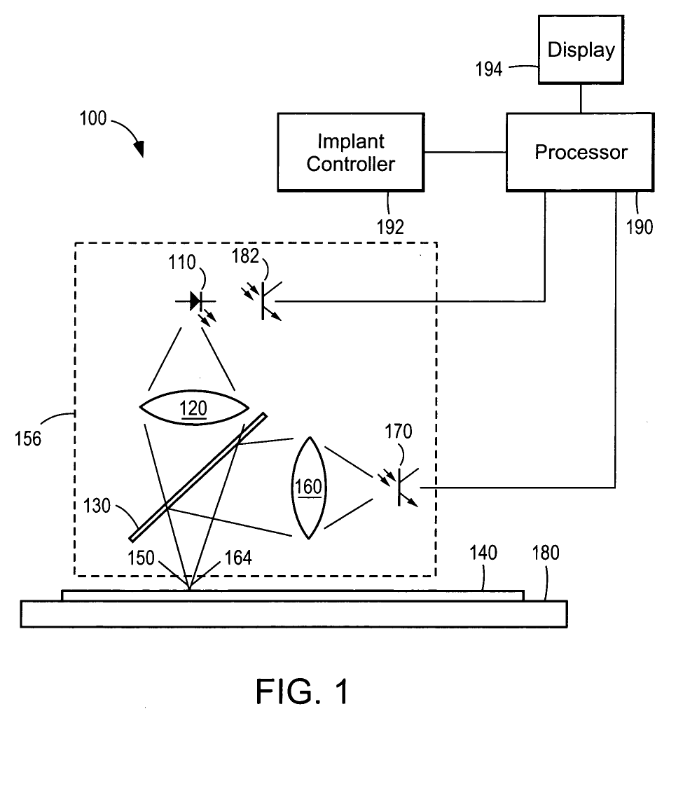

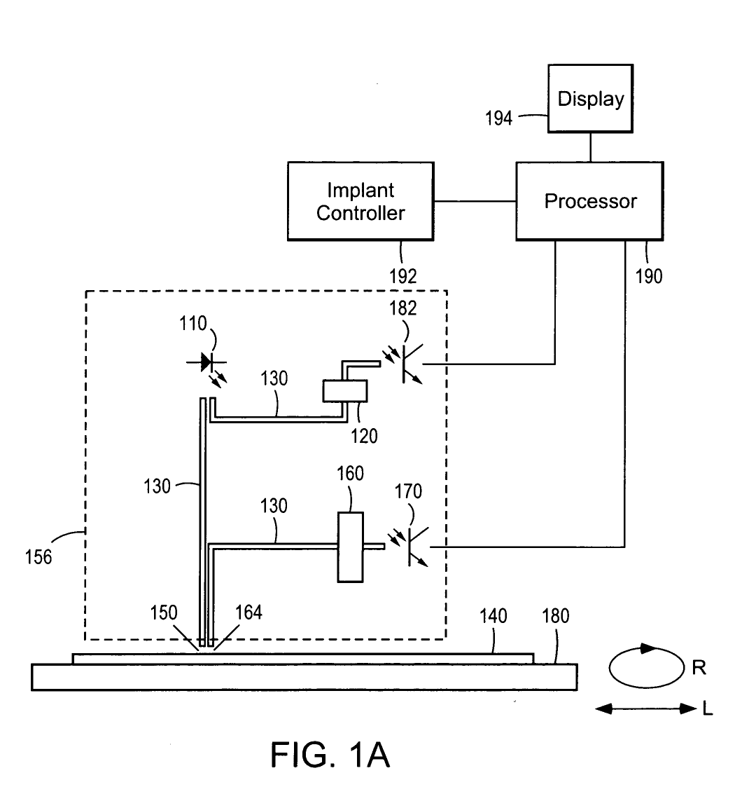

FIG. 1 shows an arrangement 100 in accordance with the invention. A light source, for example an LED 110, directs light through an objective 120 and beamsplitter 130 onto a substrate 140. The light impinges substrate 140 at an incidence location 150, and is reflected by the substrate and beamsplitter through focusing lens 160 onto a detector, such as photodiode 170. Substrate 140 is disposed on a stage 180 such that relative motion between the impinging light from source 110 and the substrate can be effected, in order to implement a substrate surface scan as described below. Either the impinging light, or the substrate, or both, can be moved in order to achieve the relative motion. A detector 182 detects light from source 110 and provides an input signal to a processor 190 for controlling desired characteristics of the illumination, for example the duration of each sampling incident or pulse, and for determining a base point against which measured illumination from photodiode 170 is compared.

The light source in the arrangement of FIG. 1 can provide either monochromatic or polychromatic light and is preferably non-coherent light. It can be one or more LEDs, or other single or multiple sources of light whose wavelength range is selected primarily based on the type of substrate under consideration. These substrates include, but are not limited to, a bare silicon (Si) substrate, a gallium arsenide (GaAs) substrate, a silicon carbide (SiC), a silicon oxide (SiO₂), and an indium phosphide (InP) substrate, with each substrate having a preferred light wavelength range that can readily determined by one of ordinary skill in the art. The substrate can be a coated substrate, for example with a thin film, or ultra-thin film (USF). Further, the substrate can be implanted over a range of energies, including low energy implantation into bare silicon wafers, or wafers with a thin oxide on the silicon. Known processes for low energy implantation, to which the present invention is applicable, include ULE (ultra-low energy) utilizing isotype separation and beam line processes and PLAD (plasma doping) implant processes.

Other factors may also be considered in selecting the wavelength range of light from light source 110, such as the implantation species in the substrate, and whether the substrate material is of the low dose, high dose or super high dose implant type. Low dose implants, whose dosage levels are in the range of about 6×10¹¹ to 3×10¹² ions/cm², are used in threshold adjust (Vt) implant applications. High dose materials, with dosage levels that are in the range of the high 10¹⁵ to low 10¹⁶ ions/cm², are used in CMOS source/drain and bipolar emitter implant applications. Super high dose materials, with dosage levels that are in the range of the mid 10¹⁶ to low 10¹⁷ ions/cm², have uses in applications such as wafer splitting, for example according to Smartcut™ techniques.

The energy of light is selected such that the impinging beam on the substrate is substantially non-destructive, particularly with respect to any implanted material in the substrate. That is, the implantation characteristics of the material should not be significantly altered by the impinging light, in order to accurately measure the nature of the implantation, for instance, and in order to ensure that consistent results are obtained over multiple readings. Based on these conditions, the substrate is considered to be in a quiescent state before and during the reading, meaning that it is not in an excited state when reading is initiated upon impingement of light from source 110, and is not, to any appreciable degree, excited by impingement of light from source 110. The latter condition—that impingement from source 110 does not appreciably excite the substrate—does not preclude some alterations in the material, which may be persistent or non-persistent. However, these alterations are not cumulative to any extent that would affect the accuracy or repeatability of the measurements performed in accordance with the invention.

Given these constraints, the intensity of light used will vary depending on the material. As a relative measure, CorMap™ units (CMU™) are used to measure the intensity of light used with different materials, and are defined as a relative measure of light intensity in the range of 0 to about 65,000. Accordingly, for a bare silicon (Si) substrate, an intensity value of about 50,000 CMU™ is preferred. For a gallium aresnide (GaAs) substrate, a value of about 50,000 CMU™ is preferred. For silicon carbide (SiC), a value of about 64,000 CMU™ is preferred. For indium phosphide (InP), a value of about 60,000 CMU™ is preferred.

Objective 120 and focusing lens 160 can each be one or more optical elements, and are merely represented in FIG. 1 as single devices for simplicity. They are part of optical system 156, which may include beam shaping, filtering and focusing optics. Objective 120 is designed to focus light onto substrate 140 to define on the surface thereof, at incidence point 150, an illumination area 164 approximately 0.8 mm² in size.

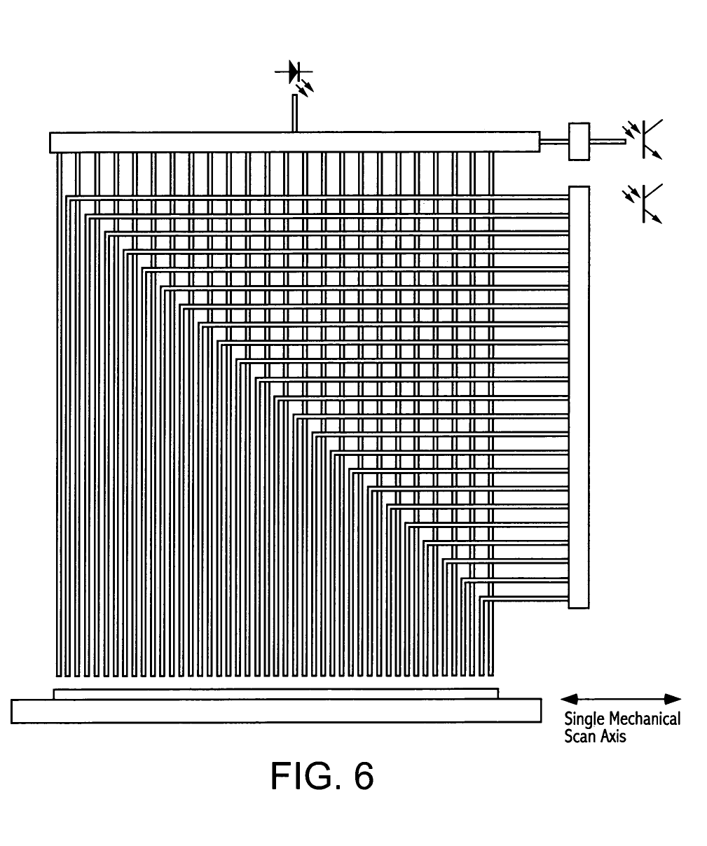

Light reflected by substrate 140 is directed to detector 170 via beamsplitter 130 and focusing lens 160. Detector 170 is any type of photodetector having one or multiple sensing elements which are sensitive to the particular light wavelengths as reflected from substrate 140. Electrical signals corresponding to the reflected light are provided by detector 170 to a processor 190, which serves to analyze the reflected light in order to determine implantation or other characteristics of the substrate 140. Implantation characteristics include one or more of implantation energy, dosage, species, depth, or other characteristics, all of which have been found to be functions of the spectral distribution and intensity of the reflected light. Thus for the case of an implanted substrate, an analysis of the reflected light is used to provide qualitative and/or quantitative indications of one or more implantation characteristics, particularly when the other characteristics are known. For example, if the energy and species are known, the dosage can be determined from the reflected light. Further, when performed over the entire substrate surface, in a prescribed scanning pattern, implant mapping can be conducted and implantation uniformity determined, as described in greater detail below. This information is in turn useful for assessing many factors during the implantation and fabrication processes. For instance, implanter performance can be assessed and the implant process can be controlled in a feedback type process performed either in real time or during subsequent implantation runs. For real time, in process operation, the information from processor 190 can be used to provide direct input and control to the implanter device, via implant controller 192, as illustrated in FIGS. 1 and 6.

It will be appreciated that the invention can be used with any implantable species, including but not limited to the commonly used electrically non-active dopants which, for a silicon substrate, include hydrogen (H+), silicon, germanium, oxygen and argon, and for a gallium arsenide (GaAr) substrate, include argon, gallium, arsenic, and hydrogen (H+).

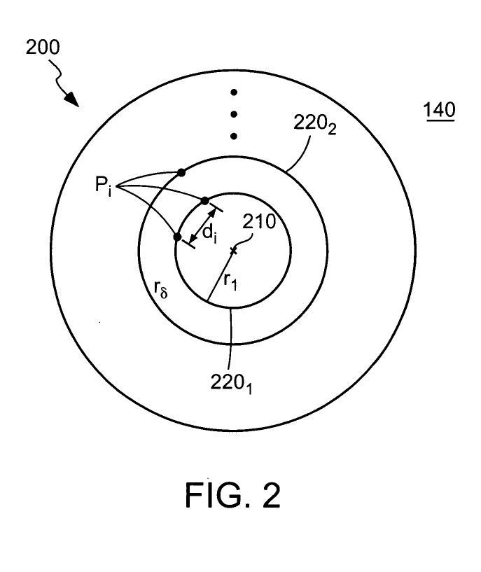

FIG. 2 shows a scanning pattern 200 representing the preferred path that illumination area 164 (FIG. 1) traverses across the surface of substrate 140 during a substrate analysis process. This scanning pattern is generally a series of concentric circles, each representing a sequence of discrete measurements taken along measurement points Pᵢ disposed in a circular path around substrate center 210. In this particular example the substrate is a 300 mm wafer, although other types of substrate, circular or otherwise, can be used, and the scanning pattern adjusted accordingly. For example, a linear pattern (not shown) can be used when the substrate is a flat panel display having a rectangular shape. Such a linear pattern would comprise a series of parallel lines representing the sequence of discrete measurements taken along the straight lines.

To achieve scanning pattern 200 of FIG. 2, relative motion between illumination area 164 (FIG. 1) and substrate 140 is effected. Preferably, the pattern begins with the innermost circle 220₁, whose circumference is traversed by for example incrementally rotating stage 180 (FIG. 1) and wafer 140 around the center of the wafer at a first distance r₁, sampling at each measurement point Pᵢ to conduct the spectral distribution and reflected light intensity measurement described above, and then moving on to the next measurement Pᵢ, and so on. At the completion of the circle 220₁, the position of the illumination area 164 is indexed radially outward, a distance of r_{δ} which may be about 1 mm, to begin the next concentric circle 220₂, and so on.

The separation between consecutive measurement points Pᵢ on a circle can be approximated as a linear distance dᵢ. This separation, along with the radial distance r_{δ} between circles 220ᵢ, is selected depending on the total number of measurements desired for each substrate. Preferably, this total number of measurements for a 300 mm a silicon wafer is about 86,700, and is about 37,700 for a 200 mm silicon wafer. The linear dᵢ and radial distances r_{δ} corresponding to these total measurements are about 0.8 mm and 1.0 mm, respectively.

Due to the relatively short duration of each measurement, it is contemplated that using the aforementioned scanning pattern, a 300 mm silicon wafer can be scanned in about 5 minutes or less, while a 200 mm silicon wafer can be scanned in about 3 minutes or less.

The scan measurements are compiled by processor 190, which generates a map of values corresponding to the measurement points on the surface of the substrate 140. This map, based on the above measurement distances and densities, can have a spacial resolution of about 0.8 mm² for either the 200 mm or the 300 mm silicon wafer.

It is also contemplated that other scanning processes can be used. In FIG. 1A, for instance, scanning can be effected by way of optical fibers 130, and suitably configured optical components. A combination of rotational and linear motions, represented by arrows R and L in FIG. 1A, which may be more compatible with some existing scanning platforms, are utilized to implement the desired scanning pattern. It will appreciated that other types of imaging, relative motion and light detection expedients may also be used in accordance with the invention, including those using two dimensional arrays of photodiodes (not show), for example.

In accordance with one method of the invention, the substrate under measurement is scanned prior to implantation, and then again after implantation. The same pattern is used in the pre-implant and post-implant scans, and mapped values corresponding to measurement points before implantation and after implantation are correlated to one another in order to obtain, for each measurement point on the surface of the substrate, a differential measurement value indicative of the implantation characteristic change attributable to the implantation process. From these values, an implantation characteristics map is generated by processor 190, which map can be used for real time or subsequent control of the implantation process. Real time control can be effected by routing processor control signals to implant controller 192.

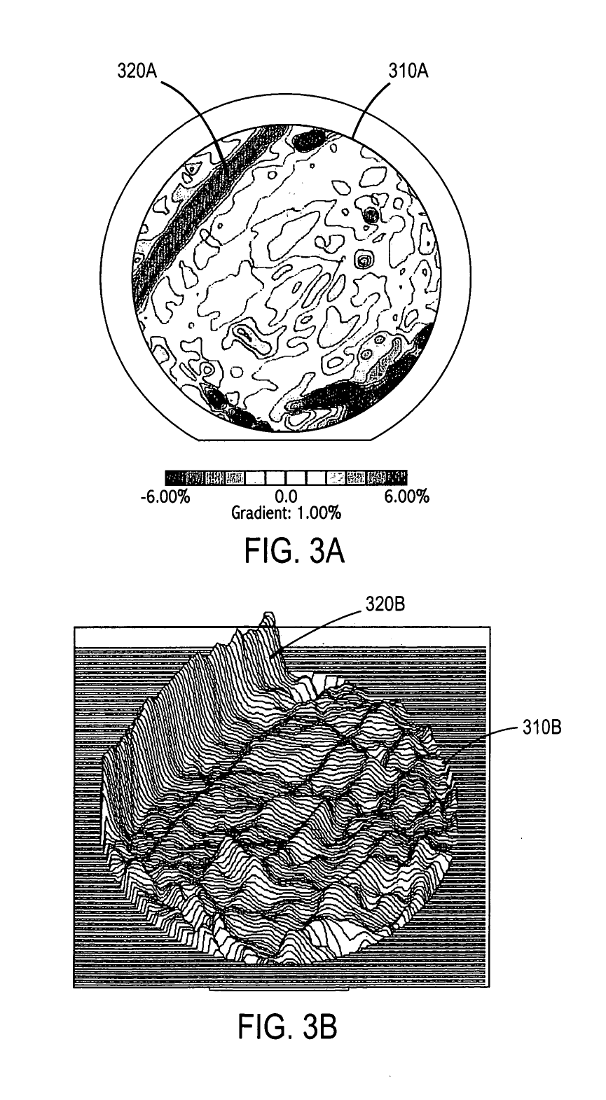

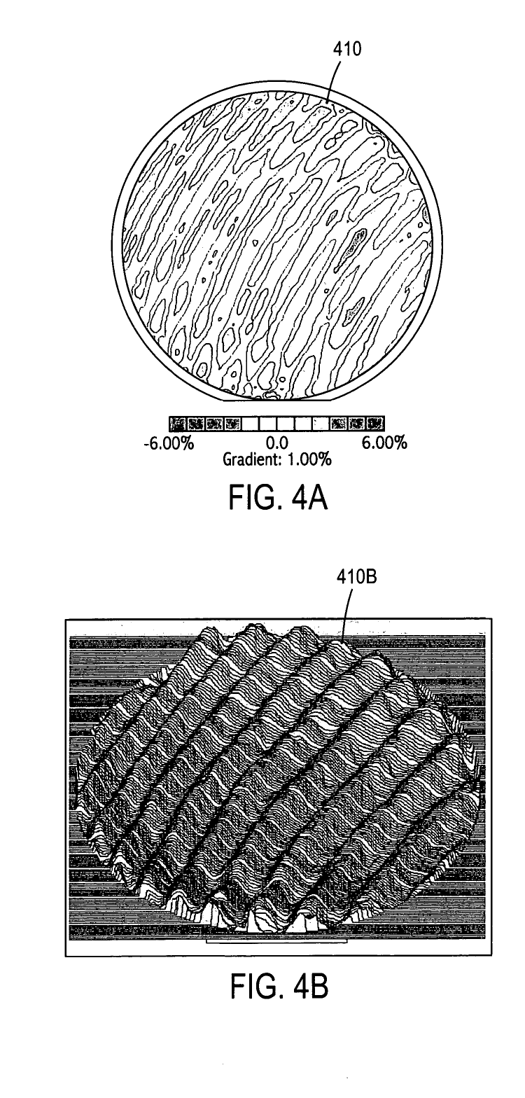

In addition, the implantation characteristics map can be displayed graphically, on a display device 194 (FIG. 1) in order to enable visualization of the implant process. The display can be a two dimensional or three dimensional view, as shown respectively in FIGS. 3A and 3B, which depict mappings 310A and 310B indicating implanter malfunction—namely, a mechanical malfunction on a batch-type implanter—resulting in an uneven implant gradient, most dramatically seen in the high gradient regions 320A and 320B. By comparison, FIGS. 4A and 4B illustrate implantation mappings 410A and 410B of acceptable uniformity, indicating a properly functioning implantor.

It will be appreciated that since in this embodiment differential measurement values are used, rather than the absolute measurements themselves, the method and process of the invention can be applied to many kinds of substrates and materials, during almost all phases of processing. In particular, it can be used to measure implantation of bare wafers without any features, or it can be used to measure implantation of wafers or other materials at various stages of fabrication, for example implantation o wafers after photomask. Since only the differences between measurements before and after implantation are needed to generate the necessary diagnosis information—that is, the differential measurement values—the effects of the particular fabrication stage at which the substrate is at are canceled out, and only the implantation characteristics are measured. Of course, other substrate characteristics, and not merely those relating to implantation, can also be measured in this manner.

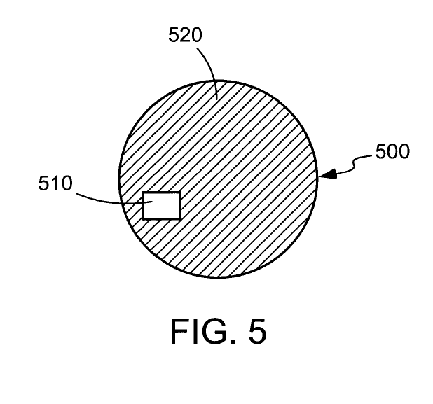

Moreover, it will be appreciated that while the implantation or other characteristics of a whole substrate are usually of interest, mandating scans of the whole substrate, in some cases only partial scans are necessary, and the scanning motion and/or software can be adjusted accordingly. In accordance with a preferred embodiment, however, if only a portion of a substrate such as a semiconductor wafer is of interest, the whole substrate is still scanned, and the portions that are not of interest are simply subtracted out. FIG. 5 is illustrative of this approach, which is generally more practical than modifying the scanning pattern and associated mechanical motions involved to focus only on the area of interest. In FIG. 5, the region of interest in wafer 500 is rectangular region 510. A scan of the whole wafer 500 is conducted, with the measurements corresponding to the shaded region 520 being simply discarded in favor of those in region 510.

The invention can also be applied for providing background map information of a substrate, without regard to subsequent measurements. For instance, an unimplanted wafer, whether bare or coated with a special sensitive coating, for example ultra sensitive film (USF) or other resist type coating, can be measured prior to implant. From this background scan measurement, data and a contour map (or other maps such as a three-dimensional map, diameter map, and so forth) can be generated to show possible imperfections in the material or in the coating, or both. A mean (average) value and standard deviation of all the data points (37,700 for a 200 mm wafer or 87,700 for a 300 mm wafer) is displayed along the map. In some instances, no implant is desired, but the substrate quality or special thin film—Si₃N₄, for instance—is to be measured and evaluated. This can be displayed directly after completion of the background scan.

It may also be desired to simply generate an implant map without resort to a differential measurement. An implant scan is performed after a substrate is implanted. The substrate is typically previously measured for a background scan, although that may not be necessary when the substrate material has shown, with statistically high confidence, to be the same day to day, week to week. According to this method, a mean value and standard deviation of all the data points is displayed along the map. The implant map can be displayed directly, without the need for the subtraction of implant from the background. This approach can be used to highlight differences in areas of the substrate or in certain details in the implant map and in the difference map. The background scan can be derived from a standard substrate or from a computer generated artificial map.

The above are exemplary modes of carrying out the invention and are not intended to be limiting. It will be apparent to those of ordinary skill in the art that modifications thereto can be made without departure from the spirit and scope of the invention as set forth in the following claims.

1. A method for measuring one or more characteristics of ion implantation in a substrate, said method comprising:
before implantation:
directing non-destructive light onto a quiescent substrate at a first set of one or more measurement points to thereby cause light reflection by the substrate; and
detecting said light reflection;
after implantation:
directing non-destructive light onto the substrate at the first set of one or more measurement points to thereby cause light reflection by the substrate; and
detecting said light reflection; and
correlating the detected light reflection before implantion to the detected light reflection after implantion to obtain one or more differential measurement values each associated with a corresponding measurement point and indicative of an implantation characteristic of the substrate at said corresponding measurement point.

2. The method of claim 1, wherein the substrate is a 200 mm semiconductor wafer and the number of measurement points is 37,700.

3. The method of claim 1, wherein the substrate is a 300 mm semiconductor wafer and the number of measurement points is 87,700.

4. The method of claim 2, wherein the scanning and detecting before implantation are performed in about 3 minutes.

5. The method of claim 2, wherein the scanning and detecting after implantation are performed in about 3 minutes.

6. The method of claim 3, wherein the scanning and detecting before implantation are performed in about 5 minutes.

7. The method of claim 3, wherein the scanning and detecting after implantation are performed in about 5 minutes.

8. The method of claim 1, wherein the substrate is a flat panel display.

9. The method of claim 1, wherein the light is directed at the substrate in accordance with a scanning pattern comprising a set of concentric circles spaced by a radial distance of about 1 mm.

10. The method of claim 1, wherein the light is from a light source comprising one or more LEDs.

11. The method of claim 1, wherein the substrate is a semiconductor wafer without features.

12. The method of claim 1, wherein the substrate is a semiconductor wafer having features fabricated thereon.

13. The method of claim 1, wherein the light comprises non-coherent polychromatic light.

14. The method of claim 10, wherein the light comprises non-coherent polychromatic light.

15. The method of claim 1, wherein the one or more characteristics include any of dopant concentration, dose, energy and depth.

16. A method for generating an implantation characteristic profile of a quiescent substrate, the method comprising:
non-destructively illuminating the quiescent substrate at a plurality of measurement points prior to implantation;
for each illuminated measurement point prior to implantation, detecting spectral distribution and intensity of reflected light;
non-destructively illuminating the quiescent substrate at a plurality of measurement points after implantation;
for each illuminated measurement point after implantation, detecting spectral distribution and intensity of reflected light; and
generating a map of differential measurement values each associated with a corresponding measurement point and indicative of an implantation characteristic of the substrate at said corresponding measurement point.

17. The method of claim 16, wherein the substrate is a 200 mm semiconductor wafer and the number of measurement point is 37,700.

18. The method of claim 16, wherein the substrate is a 300 mm semiconductor wafer and the number of measurement points is 87,700.

19. The method of claim 17, wherein the scanning and detecting prior to implantation are performed in about 3 minutes.

20. The method of claim 17, wherein the scanning and detecting after implantation are performed in about 3 minutes.

21. The method of claim 18, wherein the scanning and detecting prior to implantation are performed in about 5 minutes.

22. The method of claim 18, wherein the scanning and detecting after implantation are performed in about 5 minutes.

23. The method of claim 16, wherein the substrate is a flat panel display.

24. The method of claim 16, wherein illumination light is directed at the substrate in accordance with a scanning pattern comprising a set of concentric circles spaced by a radial distance of about 1 mm.

25. The method of claim 16, wherein illumination is from a light source comprising one or more LEDs.

26. The method of claim 16, wherein the substrate is a semiconductor wafer without features.

27. The method of claim 16, wherein the substrate is a semiconductor wafer having features fabricated thereon.

28. The method of claim 16, wherein illumination is from a non-coherent polychromatic light source.

29. The method of claim 25, wherein illumination is from a non-coherent polychromatic light source.

30. The method of claim 16, wherein the implantation characteristic profile relates to any of dopant concentration, dose, energy, and depth.

31. A device for non-destructively measuring dopant concentration in a substrate, comprising:
a light source;
a light detector generating a detection signal in response to light impinging thereon;
an optical system directing light from the light source to an illumination area on the substrate, and directing light reflected by the substrate from the illumination area onto the light detector;
a stage for relatively moving the substrate and the illumination area in first and second scanning patterns;
a processor which, during the first scanning pattern, obtains from the light detector a first set of detection signals each corresponding to a measurement point on the substrate, and during the second scanning pattern, obtains from the light detector a second set of detection signals each corresponding to each of said measurement points, such that for each measurement point, a pair of detection signals are obtained, the processor further generating a set of differential measurement values each derived from one of said pair of detection signals, said set of differential measurement values being indicative of implantation characteristic levels in the substrate, including any of dopant concentration, dose, energy, and depth.

32. The device of claim 31, wherein the substrate is a 200 mm semiconductor wafer and the number of measurement point is 37,700.

33. The device of claim 31, wherein the substrate is a 300 mm semiconductor wafer and the number of measurement point is 87,700.

34. The device of claim 32, wherein the first scanning pattern is performed in about 3 minutes.

35. The device of claim 32, wherein the second scanning is performed in about 3 minutes.

36. The device of claim 33, wherein the first scanning pattern is performed in about 5 minutes.

37. The device of claim 33, wherein the second scanning pattern is performed in about 5 minutes.

38. The device of claim 31, wherein the substrate is a flat panel display and wherein the first and second pattern are linear.

39. The device of claim 31, wherein the first and second scanning patterns each comprises a set of concentric circles spaced by a radial distance of about 1 mm.

40. The device of claim 31, wherein the light source comprises one or more LEDs.

41. The device of claim 31, wherein the substrate is a semiconductor wafer without features.

42. The device of claim 37, wherein the substrate is a semiconductor wafer having features fabricated thereon.

43. The device of claim 31, wherein the light source emits non-coherent polychromatic light.

44. The device of claim 40, wherein the LEDs emit non-coherent polychromatic light.

45. A method for characterizing a substrate, comprising:
directing non-destructive light onto a surface of a substrate in a quiescent state at a plurality of measurement points on the substrate to thereby cause light reflection by the substrate;
detecting light reflected from the substrate at the plurality of measurement points; and
using the detected reflected light to generate a map indicative of relative reflectivity across the surface of the substrate.

46. The method of claim 45, further comprising determining implantation characteristic levels in the substrate, including any of dopant concentration, dose, energy and depth, based on said map.

47. The method of claim 45, wherein the substrate is a semiconductor wafer having features formed thereon.

48. The method of claim 45, wherein the substrate is a semiconductor wafer without features.

49. The method of claim 45, wherein the substrate is ion implanted.

50. The method of claim 45, wherein the substrate surface includes a thin film.

51. The method of claim 45, wherein the number of measurement points is 37,700.

52. The method of claim 45, wherein the number of measurement points is 87,700.

53. The method of claim 45, wherein the light is non-coherent polychromatic light.

54. The method of claim 45, wherein the light is non-coherent monochromatic light.

55. A method for measuring low energy ion implantation dosage in a bare silicon test wafer implanted using plasma doping (PLAD) implantation, said method comprising:
directing non-destructive light onto the test wafer to thereby cause light reflection from the wafer;
detecting said light reflection; and
correlating the detected light reflection to ion implantation dosage based on a comparison with reflection characteristics of a bare silicon wafer background standard.

56. The method of claim 55, wherein the wafer is a 200 mm semiconductor wafer.

57. The method of claim 55, wherein the wafer is a 300 mm semiconductor wafer.

58. The method of claim 55, wherein the light is from a light source comprising one or more LEDs.

59. The method of claim 55, wherein the light comprises non-coherent polychromatic light.

60. A method for measuring low energy ion implantation dosage in a thin oxide-coated silicon test wafer implanted using plasma doping (PLAD) implantation, said method comprising:
directing non-destructive light onto the test wafer to thereby cause light reflection from the wafer;
detecting said light reflection; and
correlating the detected light reflection to ion implantation dosage based on a comparison with reflection characteristics of a thin oxide-coated silicon wafer background standard.
